(19) United States
(12) Patent Application Publication
(10) Pub. No.: US 2024/0314936 A1
(43) Pub. Date: Sep. 19, 2024

(54) PLATING APPARATUS

(71) Applicant: EBARA CORPORATION, Tokyo (JP)

(72) Inventors: Tsubasa ISHII, Tokyo (JP); Ryosuke HIWATASHI, Tokyo (JP); Masashi SHIMOYAMA, Tokyo (JP)

(21) Appl. No.: 18/589,195

(22) Filed: Feb. 27, 2024

(30) Foreign Application Priority Data
Mar. 17, 2023 (JP) 2023-042798

(51) Int. Cl. H05K 3/24

(52) U.S. Cl. CPC H05K 3/241; H05K 2203/0165; H05K 2203/0723; H05K 2203/1554

(57) ABSTRACT

In a plating apparatus, a potential sensor capable of accurately confirming flatness in thickness of a plating film is provided. The plating apparatus includes a plating tank to store a plating solution, a substrate holder that holds the substrate, an anode disposed in the plating tank to oppose the substrate held by the substrate holder, a resistor disposed between the substrate held by the substrate holder and the anode and having a plurality of holes extending through sides of the resistor facing the anode and the substrate, and a potential sensor assembly disposed between the substrate held by the substrate holder and the resistor and configured to measure a potential of the plating solution, and the potential sensor assembly includes a base plate, a plurality of potential sensors arranged on the base plate, electrical wirings formed on the base plate for taking out signals from the plurality of potential sensors, and a protective film that protects the base plate and the electrical wirings.

### CROSS REFERENCE TO RELATED APPLICATION

This application claims priority to Japanese Patent Application No. 2023-042798 filed Mar. 17, 2023, the entire contents of which are hereby incorporated by reference.

### TECHNICAL FIELD

The present invention relates to a plating apparatus, more specifically to an improvement in a potential sensor for measuring a thickness of a plating film in a plating apparatus.

### BACKGROUND ART

A plating apparatus includes a substrate holder that holds a substrate, a plating tank in which a plating solution is stored, and an anode disposed in the plating tank to oppose the substrate held by the substrate holder. In the plating apparatus, it is an important task to improve film thickness flatness of plating formed on the substrate. Conventionally, a plating apparatus including a potential sensor for measuring the thickness of the plating film has been known (see, for example, PTL 1).

### CITATION LIST

### Patent Literature

PTL 1: Japanese Patent No. 7074937

### SUMMARY OF INVENTION

### Technical Problem

It is desirable to provide a potential sensor capable of accurately confirming flatness in thickness of a plating film.

### Solution to Problem

[Form 1] According to Form 1, a plating apparatus is provided, the plating apparatus including a plating tank to store a plating solution, a substrate holder that holds the substrate, an anode disposed in the plating tank to oppose the substrate held by the substrate holder, a resistor disposed between the substrate held by the substrate holder and the anode and having a plurality of holes extending through sides of the resistor facing the anode and the substrate, and a potential sensor assembly disposed between the substrate held by the substrate holder and the resistor and configured to measure a potential of the plating solution, the potential sensor assembly including a base plate, a plurality of potential sensors arranged on the base plate, electrical wirings formed on the base plate for taking out signals from the plurality of potential sensors, and a protective film that protects the base plate and the electrical wirings.

[Form 2] According to Form 2, in the plating apparatus of Form 1, the base plate comprises a printed circuit board.

[Form 3] According to Form 3, in the plating apparatus of Form 1, the base plate is formed in an elongated plate shape, and the plurality of potential sensors are arranged along a longitudinal direction of the base plate.

[Form 4] According to Form 4, in the plating apparatus of Form 3, the plating apparatus further includes a rotation mechanism that rotates the substrate holder, and the potential sensor assembly is disposed between the substrate and the resistor so that the longitudinal direction of the base plate is along a radial direction of the rotation.

[Form 5] According to Form 5, in the plating apparatus of any one of Forms 1 to 4, the base plate includes a plurality of holes formed to be aligned with the plurality of holes in the resistor.

[Form 6] According to Form 6, in the plating apparatus of Form 5, each of the plurality of holes in the base plate is disposed at a position overlapping with one of the plurality of holes in the resistor.

[Form 7] According to Form 7, in the plating apparatus of Form 6, the plurality of holes in the base plate are provided to oppose all of the holes in the resistor which are present in a portion overlapping with an outer shape of the base plate.

[Form 8] According to Form 8, in the plating apparatus of Form 5, the holes in the base plate have a diameter equal to or greater than the diameter of the holes in the resistor.

### BRIEF DESCRIPTION OF DRAWINGS

FIG. 1 is a perspective view illustrating an overall configuration of a plating apparatus according to one embodiment;

FIG. 2 is a plan view illustrating the overall configuration of the plating apparatus according to the embodiment;

FIG. 3 is a longitudinal sectional view schematically illustrating a configuration of a plating module according to the embodiment;

FIG. 4 is a plan view illustrating a configuration of a potential sensor assembly according to the embodiment;

FIG. 5 is a schematic view illustrating a positional relation between the potential sensor assembly and a substrate during a plating process;

FIG. 6 is a plan view illustrating a configuration of a potential sensor assembly according to another embodiment; and

FIG. 7 is a perspective view illustrating the potential sensor assembly of the embodiment of FIG. 6 together with a resistor.

### DESCRIPTION OF EMBODIMENTS

Hereinafter, embodiments of the present invention will be described with reference to the drawings. In the drawings described below, the same or corresponding components are denoted with the same reference sign and will not be described in duplicate.

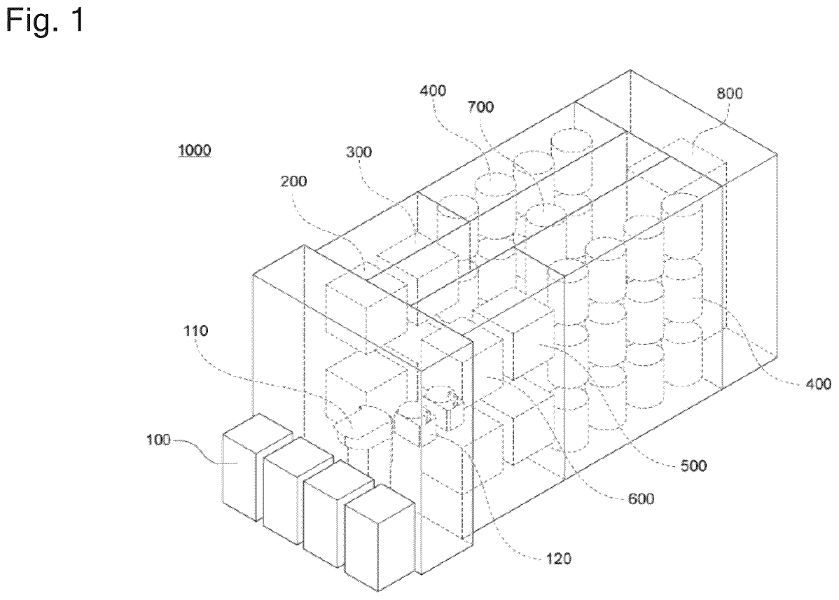

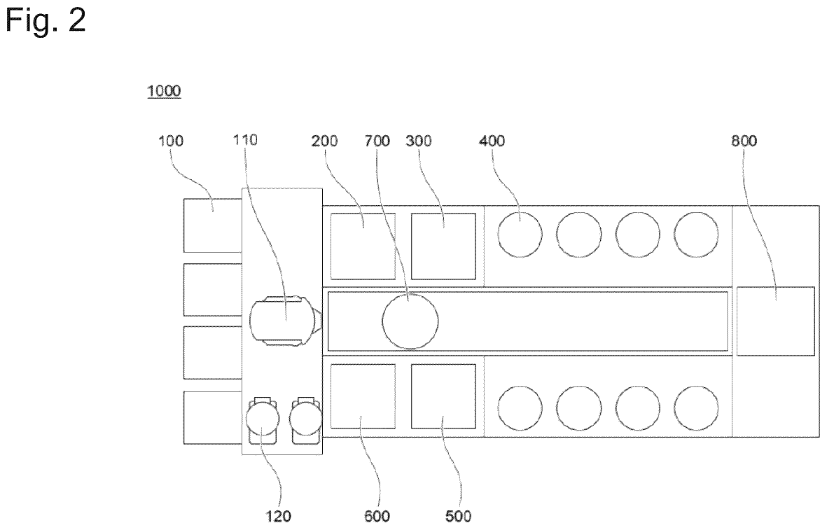

FIG. 1 is a perspective view illustrating an overall configuration of a plating apparatus of one embodiment, and FIG. 2 is a plan view of the overall configuration. As illustrated in FIGS. 1 and 2, a plating apparatus 1000 includes load ports 100, a transfer robot 110, aligners 120, pre-wet modules 200, pre-soak modules 300, plating modules 400, cleaning modules 500, spin rinse dryers 600, a transfer device 700, and a control module 800.

The load port 100 is a module for loading a substrate housed in a cassette, such as a FOUP, (not illustrated) to the plating apparatus 1000 and unloading the substrate from the plating apparatus 1000 to the cassette. While four load ports 100 are arranged in the horizontal direction in this embodiment, the number of load ports 100 and arrangement of the load ports 100 are arbitrary. The transfer robot 110 is a robot for transferring the substrate that is configured to grip or release the substrate between the load port 100, the aligner 120, and the transfer device 700. The transfer robot 110 and the transfer device 700 can perform delivery and receipt of the substrate via a temporary placement table (not illustrated) to grip or release the substrate between the transfer robot 110 and the transfer device 700.

The aligner 120 is a module for adjusting a position of an orientation flat, a notch, and the like of the substrate in a predetermined direction. While the two aligners 120 are disposed to be arranged in the horizontal direction in this embodiment, the number of aligners 120 and arrangement of the aligners 120 are arbitrary. The pre-wet module 200 wets a surface to be plated of the substrate before a plating process with a process liquid, such as pure water or deaerated water, to replace air inside a pattern formed on the surface of the substrate with the process liquid. The pre-wet module 200 is configured to perform a pre-wet process to facilitate supplying a plating solution to the inside of the pattern by replacing the process liquid inside the pattern with the plating solution during plating. While the two pre-wet modules 200 are disposed to be arranged in the vertical direction in this embodiment, the number of pre-wet modules 200 and arrangement of the pre-wet modules 200 are arbitrary.

For example, the pre-soak module 300 is configured to remove an oxidized film having a large electrical resistance present on a surface of a seed layer formed on the surface to be plated of the substrate before the plating process by etching with a process liquid, such as sulfuric acid and hydrochloric acid, and perform a pre-soak process that cleans or activates a surface of a plating base layer. While the two pre-soak modules 300 are disposed to be arranged in the vertical direction in this embodiment, the number of pre-soak modules 300 and arrangement of the pre-soak modules 300 are arbitrary. The plating module 400 performs the plating process on the substrate. There are two sets of the 12 plating modules 400 arranged by three in the vertical direction and by four in the horizontal direction, and the total 24 plating modules 400 are disposed in this embodiment, but the number of plating modules 400 and arrangement of the plating modules 400 are arbitrary.

The cleaning module 500 is configured to perform a cleaning process on the substrate to remove the plating solution or the like left on the substrate after the plating process. While the two cleaning modules 500 are disposed to be arranged in the vertical direction in this embodiment, the number of cleaning modules 500 and arrangement of the cleaning modules 500 are arbitrary. The spin rinse dryer 600 is a module for rotating the substrate after the cleaning process at high speed and drying the substrate. While the two spin rinse dryers are disposed to be arranged in the vertical direction in this embodiment, the number of spin rinse dryers and arrangement of the spin rinse dryers are arbitrary. The transfer device 700 is a device for transferring the substrate between the plurality of modules inside the plating apparatus 1000. The control module 800 is configured to control the plurality of modules in the plating apparatus 1000 and can be configured of, for example, a general computer including input/output interfaces with an operator or a dedicated computer.

An example of a sequence of the plating processes by the plating apparatus 1000 will be described. First, the substrate housed in the cassette is loaded on the load port 100. Subsequently, the transfer robot 110 grips the substrate from the cassette at the load port 100 and transfers the substrate to the aligners 120. The aligner 120 adjusts the position of the orientation flat, the notch, or the like of the substrate in the predetermined direction. The transfer robot 110 grips or releases the substrate whose direction is adjusted with the aligners 120 to the transfer device 700.

The transfer device 700 transfers the substrate received from the transfer robot 110 to the pre-wet module 200. The pre-wet module 200 performs the pre-wet process on the substrate. The transfer device 700 transfers the substrate on which the pre-wet process has been performed to the pre-soak module 300. The pre-soak module 300 performs the pre-soak process on the substrate. The transfer device 700 transfers the substrate on which the pre-soak process has been performed to the plating module 400. The plating module 400 performs the plating process on the substrate.

The transfer device 700 transfers the substrate on which the plating process has been performed to the cleaning module 500. The cleaning module 500 performs the cleaning process on the substrate. The transfer device 700 transfers the substrate on which the cleaning process has been performed to the spin rinse dryer 600. The spin rinse dryer 600 performs the drying process on the substrate. The transfer device 700 grips or releases the substrate on which the drying process has been performed to the transfer robot 110. The transfer robot 110 transfers the substrate received from the transfer device 700 to the cassette at the load port 100. Finally, the cassette housing the substrate is unloaded from the load port 100.

Note that the configuration of the plating apparatus 1000 described with reference to FIGS. 1 and 2 is merely an example, and the configuration of the plating apparatus 1000 is not limited to the configuration of FIGS. 1 and 2.

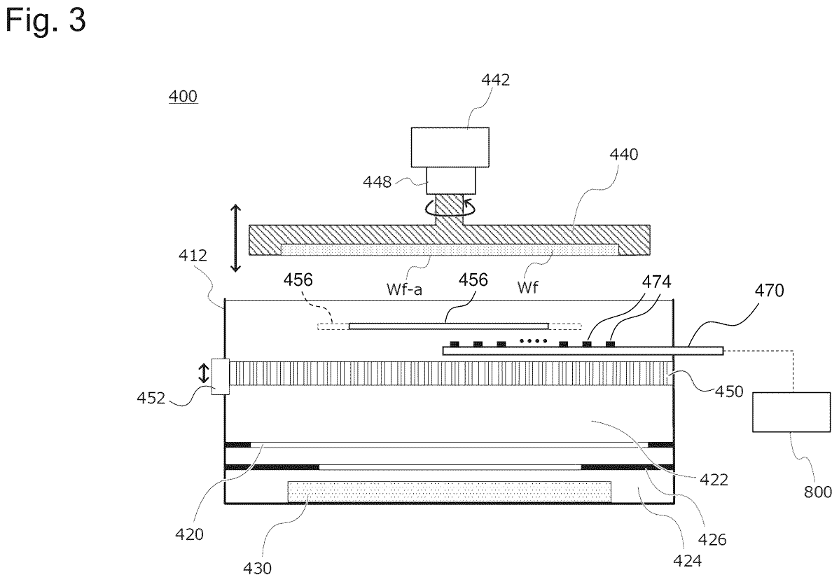

Next, a configuration of the plating module 400 will be described. Since 24 plating modules 400 in the present embodiment have the same configuration, one plating module 400 alone will be described. FIG. 3 is a longitudinal sectional view schematically illustrating the configuration of the plating module 400 of one embodiment. The plating module 400 includes a plating tank for storing the plating solution. The plating tank includes a cylindrical inner tank 412 having an open upper surface, and an unillustrated outer tank provided around the inner tank 412 so that the plating solution overflowing from an upper edge of the inner tank 412 is accumulated.

The plating module 400 includes a substrate holder 440 that holds a substrate Wf with a surface to be plated Wf-a being oriented downward. The substrate holder 440 includes a power supply contact point to supply power from an unillustrated power supply to the substrate Wf. The plating module 400 includes an elevating/lowering mechanism 442 that elevates and lowers the substrate holder 440. Further, in one embodiment, the plating module 400 includes a rotation mechanism 448 that rotates the substrate holder 440 about a vertical axis. The elevating/lowering mechanism 442 and the rotation mechanism 448 can be achieved by a known mechanism such as a motor.

The plating module 400 includes a membrane 420 that separates an inside of the inner tank 412 in the vertical direction. The inside of the inner tank 412 is divided into a cathode region 422 and an anode region 424 by the membrane 420. The cathode region 422 and the anode region 424 are each filled with the plating solution. In the present embodiment, an example where the membrane 420 is provided is described, and alternatively, the membrane 420 need not be provided.

On a bottom surface of the inner tank 412 of the anode region 424, an anode 430 is provided. Also, in the anode region 424, an anode mask 426 for adjusting an electric field between the anode 430 and the substrate Wf is disposed. The anode mask 426 is, for example, a substantially plate-shaped member made of a dielectric material and provided on a front surface of (above) the anode 430 (in FIG. 3). The anode mask 426 has an opening through which a current flowing between the anode 430 and the substrate Wf passes. The anode mask 426 is configured to have a changeable opening dimension and the opening dimension may be adjusted by the control module 800. The opening dimension means a diameter when the opening is circular, and a length of a side or longest opening width when the opening is polygonal. To change the opening dimension in the anode mask 426, a known mechanism can be adopted. In the present embodiment, an example where the anode mask 426 is provided is described, and alternatively, the anode mask 426 need not be provided. Furthermore, the membrane 420 described above may be provided in the opening of the anode mask 426.

In the cathode region 422, a resistor 450 is disposed to oppose the membrane 420. The resistor 450 is a member for uniformizing the plating process in the surface to be plated Wf-a of the substrate Wf and includes a plurality of holes extending through the anode 430 side (lower side in FIG. 3) and the substrate Wf side (upper side in FIG. 3). In the present embodiment, the resistor 450 is configured to be movable in an up-down direction in the plating tank by a drive mechanism 452, and a position of the resistor 450 is adjusted by the control module 800. While a specific material of the resistor 450 is not particularly limited, for example, a resin such as polyether ether ketone may be used.

In a vicinity of the surface of the substrate Wf in the cathode region 422, a paddle 456 for stirring the plating solution is provided. The paddle 456 is made of, for example, titanium (Ti) or a resin. The paddle 456 reciprocally moves parallel to the surface of the substrate Wf, to stir the plating solution so that sufficient metal ions are uniformly supplied to the surface of the substrate Wf during the plating of the substrate Wf. Without limiting to this example, for example, the paddle 456 may be configured to move perpendicularly to the surface of the substrate Wf. Alternatively, the plating module 400 need not include the paddle 456.

The cathode region 422 is provided with a potential sensor assembly 470 between the substrate Wf and the resistor 450. The potential sensor assembly 470 includes a plurality of potential sensors 474 for detecting a potential of the plating solution in the vicinity of the surface to be plated Wf-a of the substrate Wf. A detection signal of the potential detected by each of the potential sensors 474 is inputted into the control module 800. When the plating module 400 includes the paddle 456, the potential sensor assembly 470 is disposed at a position that does not interfere with the paddle 456. For example, as illustrated in FIG. 3, the potential sensor assembly 470 can be disposed between the paddle 456 and the resistor 450. The potential sensor assembly 470 may be disposed in contact with the surface of the resistor 450.

In one embodiment, a reference potential sensor (unillustrated) connected to the ground may be provided at a location where a change in potential is comparatively small in the plating tank, and a difference between a potential detected by this reference potential sensor and the potential detected by the potential sensor 474 may be acquired. Changes in potential measured by the potential sensors 474 are exceedingly small and therefore susceptible to noise. Noise can be reduced by using the difference between the potential detected by the reference potential sensor connected to the ground and the potential detected by the potential sensor 474.

The control module 800 can estimate a thickness of a plating film formed on the substrate Wf, based on a value of the potential detected by the potential sensor 474 (or the difference between the potential detected by the potential sensor 474 and the potential detected by the reference potential sensor). Alternatively, the control module 800 may estimate a distribution of a plating current in the surface of the substrate during the plating process based on the detection signals from the potential sensors 474 and estimate a film thickness distribution of the plating film on the substrate based on the estimated distribution of the plating current.

Also, the control module 800 may detect an endpoint of the plating process or may predict a time to the endpoint of the plating process, based on a detection value of the potential sensor 474 (or the difference between the potential detected by the potential sensor 474 and the potential detected by the reference potential sensor). Alternatively, the control module 800 may end the plating process when the film thickness of the plating film estimated based on the detection value of the potential sensor 474 reaches a desired thickness. Alternatively, the control module 800 may calculate a film thickness increase rate from the film thickness of the plating film that is estimated based on the detection value of the potential sensor 474 and may predict a time until the desired thickness of the plating film is reached, that is, the time to the endpoint of the plating process based on the obtained film thickness increase rate.

The plating process in the plating module 400 will be described. By immersing the substrate Wf in the plating solution of the cathode region 422 by use of the elevating/lowering mechanism 442, the substrate Wf is exposed to the plating solution. By applying a voltage between the anode 430 and the substrate Wf in this state, the plating module 400 can perform the plating process on the surface to be plated Wf-a of the substrate Wf. In one embodiment, the plating process is performed while rotating the substrate holder 440 by use of the rotation mechanism 448. Through the plating process, a conductive film (plating film) is precipitated on the surface to be plated Wf-a of the substrate Wf. During the plating process, the potential is measured by each of the potential sensors 474 on the potential sensor assembly 470. When the potential sensor 474 performs measurement with the rotation of the substrate holder 440 (substrate Wf), the potential can be measured for multiple points in the circumferential direction of the substrate Wf or over the entire circumferential direction. The control module 800 then estimates the film thickness of the plating film based on the value of the potential that is detected by the potential sensor 474. This makes it possible to grasp a change in film thickness of the plating film formed on the surface to be plated Wf-a of the substrate Wf in real time during the plating process.

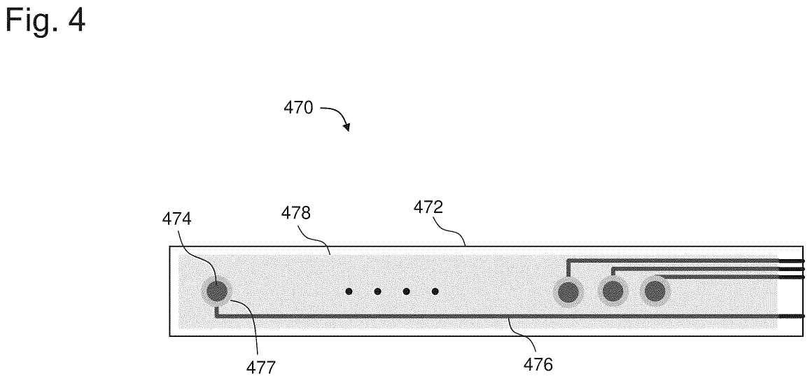

FIG. 4 is a plan view illustrating a configuration of the potential sensor assembly 470 according to one embodiment. FIG. 4 illustrates a view of the potential sensor assembly 470 from a direction perpendicular to the resistor 450 (for example, from the upper side in FIG. 3). The potential sensor assembly 470 is configured to include the plurality of potential sensors 474 mounted on a base plate 472. The base plate 472 is a thin plate-shaped member. For example, the base plate 472 may have a thickness (dimension perpendicular to the paper surface in FIG. 4) of several millimeters or less, more preferably 1 mm or less. A material of the base plate 472 is not particularly limited and is preferably a dielectric such as a resin. Alternatively, the base plate 472 may comprise a generally available printed circuit board.

On the base plate 472, a plurality of electrical wirings 476 and pads 477 are formed, and the potential sensors 474 are mounted on the respective pads 477. The potential sensors 474 are electrically connected to the pads 477, respectively, and the potential detection signals from the potential sensors 474 are sent to the control module 800 via the electrical wirings 476. A protective film 478 covering the base plate 472 and the electrical wirings 476 is further provided on the base plate 472. The protective film 478 is preferably made of, for example, a material that is resistant to the plating solution.

In the illustrative potential sensor assembly 470 of FIG. 4, the base plate 472 is configured in a shape elongated in one direction, and the plurality of potential sensors 474 are arranged in a row along a longitudinal direction of the elongated base plate 472. For example, a length of the base plate 472 in the longitudinal direction (dimension in a left-right direction in FIG. 4) may be about the same as a radius of the substrate Wf to be plated, and a width of the base plate 472 (dimension in an up-down direction in FIG. 4) may be large enough to provide sufficient space for mounting the potential sensors 474 and sufficient mechanical strength of the elongated base plate 472 (e.g., about 10 to 20 mm).

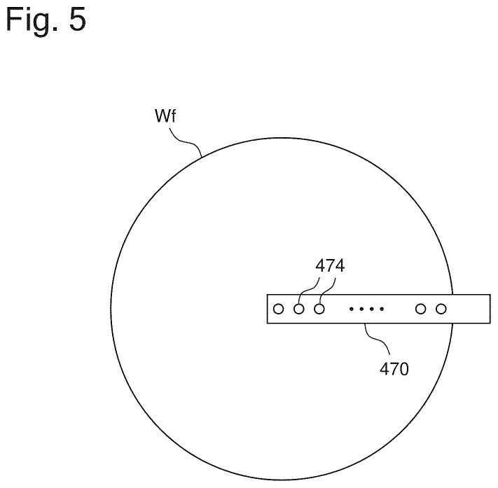

FIG. 5 is a schematic view illustrating a positional relation between the illustrative potential sensor assembly 470 of FIG. 4 and the substrate Wf during the plating process. As illustrated in FIG. 5, the potential sensor assembly 470 is disposed relative to the substrate Wf so that its longitudinal direction is along a radial direction of the substrate Wf and a tip of the potential sensor assembly 470 reaches near the center of the substrate Wf. Such an arrangement allows the plurality of potential sensors 474 of the potential sensor assembly 470 to detect potentials at multiple points arranged along the radial direction of the substrate Wf from near the center of the substrate Wf to an edge of the substrate Wf. Furthermore, when the plating process is performed while rotating the substrate holder 440 by use of the rotation mechanism 448, the plurality of potential sensors 474 are moved relative to the substrate Wf and the potential sensors 474 of the potential sensor assembly 470 can detect potentials at multiple points over the entire surface of the substrate Wf.

Thus, the potential sensor assembly 470, being of low profile, according to one embodiment can therefore be easily disposed between the substrate Wf and the resistor 450 even in the plating module 400 with a configuration where a gap between the substrate Wf and the resistor 450 is not very large and can be disposed so as to avoid interference with the paddle 456 (see FIG. 3). Since the potential sensor assembly 470 according to one embodiment has such an elongated shape as illustrated in FIG. 4, the potential sensor assembly can be disposed to reach near the center of the substrate Wf while minimizing influences on an electric field in the vicinity of the surface to be plated Wf-a of the substrate Wf. This allows potential measurements to be made at multiple points over a wide range of substrate Wf.

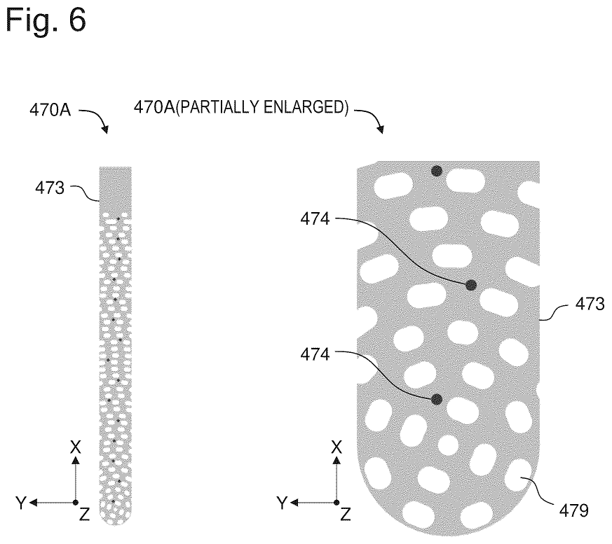

FIG. 6 is a plan view illustrating a configuration of a potential sensor assembly 470 according to another embodiment (hereinafter, the potential sensor assembly of the embodiment of FIG. 6 is referred to as 470A to distinguish it from the embodiment of FIG. 4). FIG. 6 illustrates a view of the potential sensor assembly 470A from a direction perpendicular to a resistor 450 (for example, from the upper side in FIG. 3). The potential sensor assembly 470A of the embodiment of FIG. 6 comprises a base plate 473 having a different shape from the base plate 472 in the potential sensor assembly 470 of the embodiment of FIG. 4. The configuration of the potential sensor assembly 470A other than the base plate 473 is the same as that of the potential sensor assembly 470, and redundant description is not made. For convenience, FIG. 6 illustrates only a plurality of potential sensors 474 mounted on the base plate 473, while the electrical wirings 476, pads 477 and protective film 478 are not shown.

As illustrated in FIG. 6, in the base plate 473, a plurality of holes 479 are formed. The holes 479 extend through the base plate 473 in a direction perpendicular to the paper surface in FIG. 6. Therefore, the holes 479 in the base plate 473 fluidly communicate between a resistor 450 side of the potential sensor assembly 470A disposed in an inner tank 412 of a plating tank and a substrate Wf side.

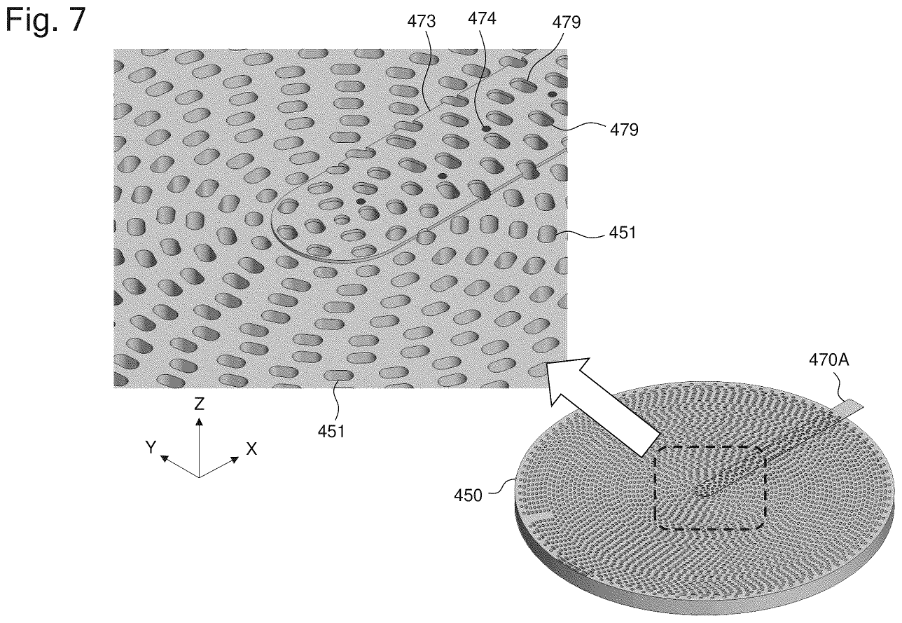

FIG. 7 is a perspective view illustrating, together with a resistor 450, the potential sensor assembly 470A of the embodiment of FIG. 6 that is disposed between the resistor 450 and a substrate Wf in an inner tank 412 of a plating tank. For clarity, the substrate Wf and a substrate holder 440 are not shown in FIG. 7. As described above with reference to FIG. 3, the resistor 450 includes a plurality of holes 451 extending through the anode 430 side (lower side in FIG. 7) and the substrate Wf side (upper side in FIG. 7). In the present embodiment, shape and layout of the holes 451 in the resistor 450 are not particularly limited and, for example, those disclosed in Japanese Patent No. 6906729 (FIG. 4, etc.) can be adopted.

As illustrated in FIG. 7, the potential sensor assembly 470A is disposed in the vicinity of or in contact with an upper surface of the resistor 450 (i.e., the surface directed toward the substrate Wf). Holes 479 formed in a base plate 473 of the potential sensor assembly 470A are aligned with the holes 451 in the resistor 450. That is, each of the holes 479 in the base plate 473 is formed at a position overlapping with one of holes 451 in the resistor 450 when the potential sensor assembly 470A is viewed from a direction perpendicular to the resistor 450. In other words, each hole 479 of the base plate 473 is provided to oppose the hole 451 of the resistor 450. The base plate 473 preferably includes the holes 479 at positions corresponding to all of the holes 451 in the resistor 450 in a portion overlapping with an elongated shape of the base plate 473 so as not to shield the respective holes 451 in the resistor 450. In order not to shield the holes 451 in the resistor 450, the holes 479 in the base plate 473 preferably have a diameter equal to or greater than the diameter of the holes 451 in the resistor 450.

Thus, since the potential sensor assembly 470A includes the holes 479 aligned with the holes 451 of the resistor 450, influences on an electric field that is formed in a plating solution between the resistor 450 and the substrate Wf can be reduced. Therefore, by using the potential sensor assembly 470A of the present embodiment, the potential in the vicinity of the surface to be plated Wf-a of the substrate Wf can be measured with high accuracy.

Furthermore, since the potential sensor assembly 470A includes the same configuration as the potential sensor assembly 470 described above in portions other than the holes 479 of the base plate 473, the potential sensor assembly 470A has the same effect as the potential sensor assembly 470. That is, the potential sensor assembly 470A, being of low profile, can therefore be easily disposed between the substrate Wf and the resistor 450 even in the plating module 400 with a configuration where a gap between the substrate Wf and the resistor 450 is not exceptionally large and can be disposed so as to avoid interference with the paddle 456. Since the potential sensor assembly 470A according to the present embodiment has the elongated shape and includes the holes 479 that do not shield the holes 451 in the resistor 450, the potential sensor assembly 470A can be disposed to reach near the center of the substrate Wf while minimizing influences on an electric field in the vicinity of the surface to be plated Wf-a of the substrate Wf. This allows highly accurate potential measurements to be made at multiple points over a wide range of substrate Wf.

The embodiments of the present invention have been described above based on several examples, and the above embodiments of the present invention are described to facilitate understanding of the present invention and are not intended to limit the present invention. Needless to say, the present invention may be changed or modified without departing from the spirit, and the present invention includes equivalents to the invention. Also, in a range in which at least some of the above-described problems can be solved or a range in which at least some of effects are exhibited, arbitrary combination or omission of respective constituent components described in claims and description is possible.

### REFERENCE SIGNS LIST

1000 plating apparatus
100 load port
110 transfer robot
120 aligner
200 pre-wet module
300 pre-soak module
400 plating module
500 cleaning module
600 spin rinse dryer
700 transfer device
800 control module
412 inner tank
420 membrane
422 cathode region
424 anode region
426 anode mask
430 anode
440 substrate holder
442 elevating/lowering mechanism
448 rotation mechanism
450 resistor
451 hole
452 drive mechanism
456 paddle
470 potential sensor assembly
470A potential sensor assembly
472 base plate
473 base plate
474 potential sensor
476 electrical wiring
477 pad
478 protective film
479 hole

What is claimed is:

1. A plating apparatus comprising:
a plating tank to store a plating solution,
a substrate holder that holds a substrate,
an anode disposed in the plating tank to oppose the substrate held by the substrate holder,
a resistor disposed between the substrate held by the substrate holder and the anode and having a plurality of holes extending through sides of the resistor facing the anode and the substrate, and
a potential sensor assembly disposed between the substrate held by the substrate holder and the resistor and configured to measure a potential of the plating solution,
the potential sensor assembly including:
a base plate,
a plurality of potential sensors arranged on the base plate,
electrical wirings formed on the base plate for taking out signals from the plurality of potential sensors, and
a protective film that protects the base plate and the electrical wirings.

2. The plating apparatus according to claim 1, wherein the base plate comprises a printed circuit board.

3. The plating apparatus according to claim 1, wherein the base plate is formed in an elongated plate shape, and
the plurality of potential sensors are arranged along a longitudinal direction of the base plate.

4. The plating apparatus according to claim 3, further comprising:
a rotation mechanism that rotates the substrate holder, wherein the potential sensor assembly is disposed between the substrate and the resistor so that the longitudinal direction of the base plate is along a radial direction of the rotation.

5. The plating apparatus according to claim 1, wherein the base plate includes a plurality of holes formed to be aligned with the plurality of holes in the resistor.

6. The plating apparatus according to claim 5, wherein each of the plurality of holes in the base plate is disposed at a position overlapping with one of the plurality of holes in the resistor.

7. The plating apparatus according to claim 6, wherein the plurality of holes in the base plate are provided to oppose all of the holes in the resistor which are present in a portion overlapping with an outer shape of the base plate.

8. The plating apparatus according to claim 5, wherein the holes in the base plate have a diameter equal to or greater than the diameter of the holes in the resistor.
